(19) United States
(12) Patent Application Publication
(10) Pub. No.: US 2025/0365019 A1
(43) Pub. Date: Nov. 27, 2025

(54) LOW DENSITY PARITY CHECK (LDPC) DECODING

(71) Applicant: Samsung Electronics Co., Ltd., Suwon-si (KR)

(72) Inventors: Heping Wan, Plano, TX (US); Joonyoung Cho, Portland, OR (US); Min Jang, Suwon-si (KR)

(21) Appl. No.: 19/072,946

(22) Filed: Mar. 6, 2025

Related U.S. Application Data
(60) Provisional application No. 63/650,982, filed on May 23, 2024.

(51) Int. Cl. H03M 13/11

(52) U.S. Cl. CPC H03M 13/1131; H03M 13/1128; H03M 13/1177

(57) ABSTRACT

Decoding low-density parity check (LDPC) codes in a communication system includes identifying a set of indices of variable nodes (VNs) having log-likelihood ratios (LLRs) greater than a threshold, Indices of parity check matrix (PCM) rows are divided into subsets each including a same number of non-zero row elements at indices of punctured VNs. The subsets of the indices of the PCM rows are ordered based on the number of non-zero row elements at the indices of the punctured VNs. A schedule is generated based on the ordered subsets of the indices of the PCM rows. Layered LDPC decoding is performed according to the schedule.

### CROSS-REFERENCE TO RELATED AND CLAIM OF PRIORITY

The present application claims priority under 35 U.S.C. § 119(e) to U.S. Provisional Patent Application No. 63/650,982 filed on May 23, 2024, which is hereby incorporated by reference in its entirety.

### TECHNICAL FIELD

The present disclosure relates generally to low density parity check codes and, more specifically, to improving throughput with low density parity check codes with acceptable error rate loss.

### BACKGROUND

Wireless communication has been one of the most successful innovations in modern history. Recently, the number of subscribers to wireless communication services exceeded five billion and continues to grow quickly. The demand of wireless data traffic is rapidly increasing due to the growing popularity among consumers and businesses of smart phones and other mobile data devices, such as tablets, “note pad” computers, net books, eBook readers, and machine type of devices. In order to meet the high growth in mobile data traffic and support new applications and deployments, improvements in radio interface efficiency and coverage are of paramount importance. To meet the demand for wireless data traffic having increased since deployment of 4G communication systems, and to enable various vertical applications, 5G communication systems have been developed and are currently being deployed.

### SUMMARY

The present disclosure relates to scheduling during layered decoding of low density parity check codes.

In an embodiment, a method for decoding low-density parity check (LDPC) codes in a communication system includes identifying a set of indices of variable nodes (VNs) having log-likelihood ratios (LLRs) greater than a threshold. The method also includes dividing indices of parity check matrix (PCM) rows into subsets each including a same number of non-zero row elements at indices of punctured VNs. The method further includes ordering the subsets of the indices of the PCM rows based on the number of non-zero row elements at the indices of the punctured VNs. The method still further includes generating a schedule based on the ordered subsets of the indices of the PCM rows. The method includes performing layered LDPC decoding according to the schedule.

In another embodiment, an apparatus for decoding low-density parity check (LDPC) codes in a communication system includes a transceiver configured to receive a signal having an associated LDPC code and at least one processor coupled to the transceiver and configured to decode the LDPC code. The processor is configured to identify a set of indices of variable nodes (VNs) having log-likelihood ratios (LLRs) greater than a threshold. The processor is also configured to divide indices of parity check matrix (PCM) rows into subsets each including a same number of non-zero row elements at indices of punctured VNs. The processor is further configured to order the subsets of the indices of the PCM rows based on the number of non-zero row elements at the indices of the punctured VNs. The processor is still further configured to generate a schedule based on the ordered subsets of the indices of the PCM rows, and to perform layered LDPC decoding according to the schedule.

In yet another embodiment, a non-transitory machine readable medium includes instructions that, when executed by at least one processor of an electronic device, cause the electronic device to identify a set of indices of variable nodes (VNs) having log-likelihood ratios (LLRs) greater than a threshold. The instructions, when executed by the at least one processor of the electronic device, also cause the electronic device to divide indices of parity check matrix (PCM) rows into subsets each including a same number of non-zero row elements at indices of punctured VNs. The instructions, when executed by the at least one processor of the electronic device, further cause the electronic device to order the subsets of the indices of the PCM rows based on the number of non-zero row elements at the indices of the punctured VNs. The instructions, when executed by the at least one processor of the electronic device, still further cause the electronic device to generate a schedule based on the ordered subsets of the indices of the PCM rows. The instructions, when executed by the at least one processor of the electronic device, cause the electronic device to perform layered LDPC decoding according to the schedule.

Before undertaking the DETAILED DESCRIPTION below, it may be advantageous to set forth definitions of certain words and phrases used throughout this patent document. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrase “associated with,” as well as derivatives thereof, means to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” means any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

Moreover, various functions described below can be implemented or supported by one or more computer programs, each of which is formed from computer readable program code and embodied in a computer readable medium. The terms “application” and “program” refer to one or more computer programs, software components, sets of instructions, procedures, functions, objects, classes, instances, related data, or a portion thereof adapted for implementation in a suitable computer readable program code. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

Definitions for other certain words and phrases are provided throughout this patent document. Those of ordinary skill in the art should understand that in many if not most instances, such definitions apply to prior as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example wireless network within which LDPC decoding may be implemented according to embodiments of the present disclosure;

FIG. 2 illustrates an example gNB within which LDPC decoding may be implemented according to embodiments of the present disclosure;

FIG. 3 illustrates an example UE within which decoding of low-density parity check codes may be implemented according to embodiments of the present disclosure;

FIG. 4A and FIG. 4B illustrate an example of wireless transmit and receive paths, respectively, within the gNB of FIG. 2 and/or the UE of FIG. 3;

FIG. 5 illustrates a flowchart of an example procedure for LDPC decoding according to embodiments of the present disclosure;

FIG. 6 illustrates a diagram of an example of a constellation and labeling rule of modulation for use with LDPC decoding according to embodiments of the present disclosure;

FIG. 7 is a flowchart of an example procedure for LDPC decoding according to embodiments of the present disclosure;

FIG. 8 illustrates an example of a parity check matrix of LDPC codes for use with LDPC decoding according to embodiments of the present disclosure;

FIG. 9 is a flowchart of an example procedure for layered decoding according to embodiments of the present disclosure;

FIG. 10 is a flowchart of an example procedure for identifying a set of indices of variable nodes according to embodiments of the present disclosure;

FIG. 11 is a flowchart of an alternative example procedure for layered decoding according to embodiments of the present disclosure;

FIGS. 12A and 12B illustrate comparisons between LDPC decoding without and with scheduling improvements in accordance with the present disclosure;

FIGS. 13 and 13A through 13E illustrate a Tanner graph representing LDPC code and decoding operations according to embodiments of the present disclosure; and

FIG. 14 is pseudo-code for a layer-scheduled LDPC decoding algorithm according to embodiments of the present disclosure.

### DETAILED DESCRIPTION

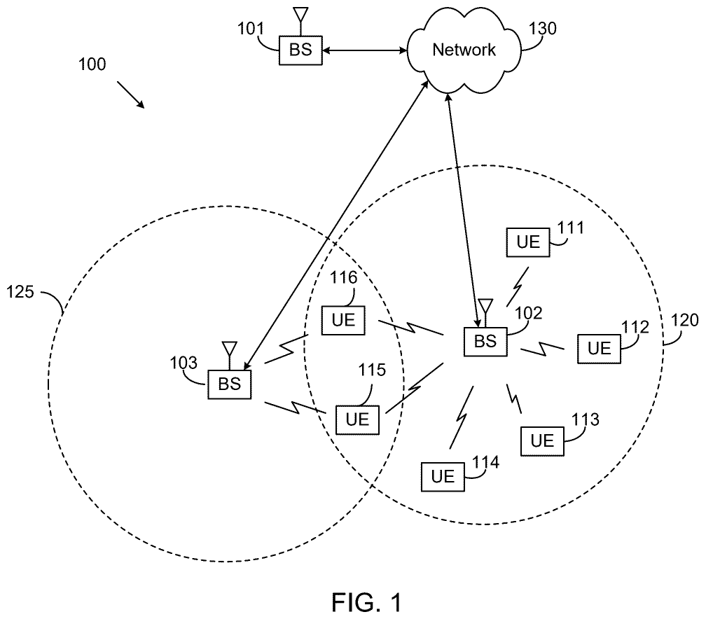

FIGS. 1-12B, discussed below, and the various, non-limiting embodiments used to describe the principles of the present disclosure in this patent document are by way of illustration only and should not be construed in any way to limit the scope of the disclosure. Those skilled in the art will understand that the principles of the present disclosure may be implemented in any suitably arranged system or device.

Low-density parity-check (LDPC) codes have been widely applied to wireless communications because LDPC codes are able to approach channel capacity asymptotically using belief propagation (BP) decoding. A LDPC code of dimension K and code length N are defined by the parity check matrix (PCM) H_{(N-K)×N}. A valid LDPC codeword v={v₀, v₁, . . . , v_{N-1}} must satisfy H_{(N-K)×N}×v^{T}=0_{(N-K)×1}—that is, v must satisfy N−K check equations, each of which corresponds to a row of H. One example of an (N=10, K=5) LDPC code is:

$$H = [ \begin{matrix}1 & 1 & 1 & 1 & 0 & 0 & 0 & 0 & 0 & 0 \\ 1 & 0 & 0 & 0 & 1 & 1 & 1 & 0 & 0 & 0 \\ 0 & 1 & 0 & 0 & 1 & 0 & 0 & 1 & 1 & 0 \\ 0 & 0 & 1 & 0 & 0 & 1 & 0 & 1 & 0 & 1 \\ 0 & 0 & 0 & 1 & 0 & 0 & 1 & 0 & 1 & 1\end{matrix} ] .$$

Each row of the above example parity check matrix H is v={v₀, v₁, v₂, v₃, v₄, v₅, v₆, v₇, v₈, v₉}. Note that, for example, v₀⊕v₁⊕v₂⊕v₃=0 for the first row, and v₃⊕v₆⊕v₈⊕v₉=0 for the last row. Similar statements can be written for the remaining rows.

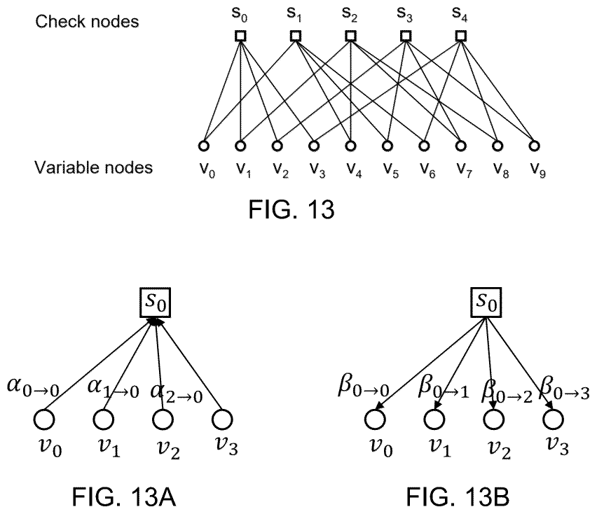

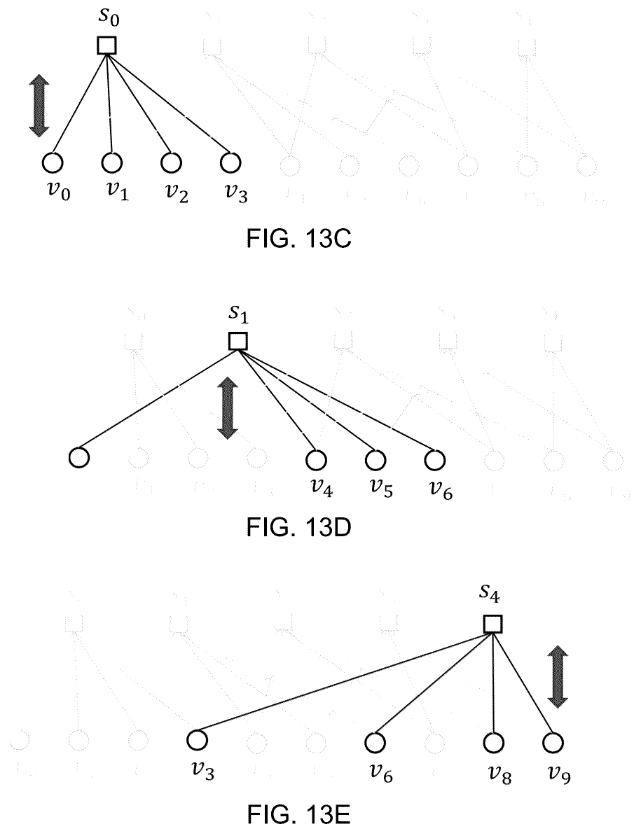

As shown in FIG. 13, LDPC codes can also be represented by the Tanner graph (where the example in FIG. 13 corresponds to the example parity check matrix H above), which is composed of two types of nodes: check nodes (CNs) and variable nodes (VNs). There are (N−K) CNs, one for each check equation, and N VNs, one for each code bit. There exists an edge connection CN j and VN i whenever h_{j,i}=1. There exists a one-to-one mapping between the PCM and the Tanner graph.

Conventionally, BP decoding is equipped with flooding schedule where all VNs are processed in parallel in the V2C stage and all CNs are processed in parallel in the C2V stage. However, the flooding schedule requires multiple iterations to achieve a target block error rate (BLER) due to its low convergence speed.

In layered decoding [1], CNs are processed in a given order instead of in parallel. Layered decoding is fulfilled by iteratively exchanging log likelihood ratios (LLRs) between CNs and VNs which are neighbors. The messages that can be updated in a Tanner graph include: a posteriori LLRs (AP-LLRs) λᵢ at VN i; variable-to-check (V2C) message α_{i→j}, which is the message passed from VN i to (neighboring) CN j; and check-to-variable (C2V) message β_{j→i}, which is the message passed from CN j to (neighboring) VN i. FIG. 13A illustrates V2C messages for a portion of the Tanner graph of FIG. 13, and FIG. 13B illustrates C2V messages.

Other notations used herein include: [symbol] ⱼ={VN indices connected to CN j}, e.g., [symbol] ₀={0,1,2,3}; [symbol] _{j\i}={VN indices connected to CN j}−{i}, e.g., [symbol] _{0\1}={0,2,3}; [symbol] ⱼ={CN indices connected to VN i}, e.g., [symbol] ₁={0,2}; and [symbol] _{i\j}={CN indices connected to VN i}−{j}, e.g., [symbol] _{1\0}={2}.

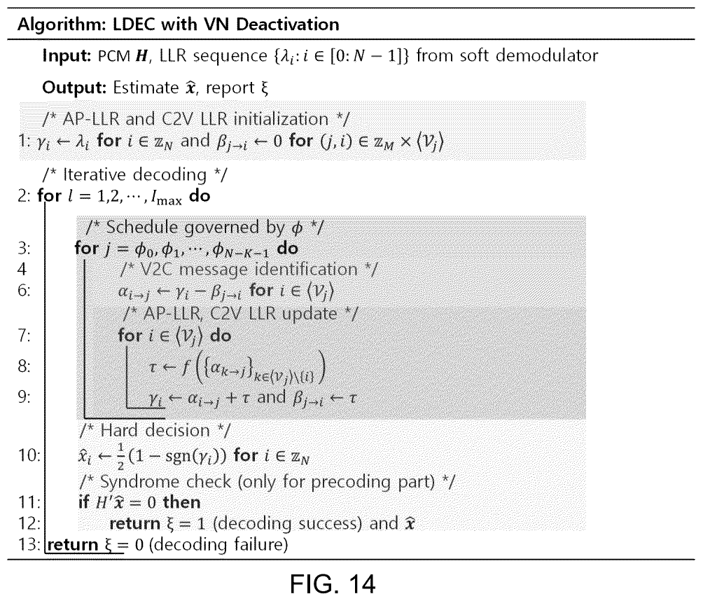

FIG. 14 is pseudo-code for a layer-scheduled LDPC decoding algorithm The schedule refers to the order of processing rows/CNs, which is determined by {ϕ₀, ϕ₁, . . . , ϕ_{N-K-1}} at step 3 in FIG. 14. {ϕ₀, ϕ₁, . . . , ϕ_{N-K-1}} is a permuted version of [0:N−K−1]. The number of iterations required to achieve a desired block level error rate (BLER) is affected by the schedule. FIG. 13A corresponds to the messages at step 6 of FIG. 14, and FIG. 13B corresponds to the messages at steps 7-9.

FIG. 13C through FIG. 13E emphasize portions of the Tanner graph of FIG. 13 to highlight message exchanges for different values of j during layered decoding following a natural order. FIG. 13C illustrates message updates when j=0, and FIG. 13D illustrates message updates when j=1. For simplicity, message updates when j=2 when j=3 are not shown, but FIG. 13E illustrates message updates when j=4. The next iteration would resume with j=0 (FIG. 13C).

LDPC codes are currently used for 5G/NR data channels and will (in high probability) continue to be used in future cellular systems. However, channel decoding is one of the most time-consuming procedures, making improvement of the throughput an LDPC decoder (and therefore the throughput of cellular systems) important.

To improve throughput of an LDPC layer decoder, the present disclosure seeks to increase convergence speed. The faster that the layered decoder converges, the lower the number of iterations required to achieve a desired block error rate (BLER). The present disclosure seeks to double throughput of a software-implemented layered decoder (SW-LDEC), with an acceptable error rate.

The following documents and standards descriptions are hereby incorporated by reference into the present disclosure as if fully set forth herein:
[1] Hocevar, Dale E. “A reduced complexity decoder architecture via layered decoding of LDPC codes.” IEEE Workshop onSignal Processing Systems, 2004.
[2] Jang, Min, et al. “Analysis and design of QC-LDPC coded BICM ensembles based on RCA density evolution.” IEEE Transactions on Communications 70.4 (2022): 2183-2199.
[3] Jang, Min, et al. “A Design of Layered Decoding for QC-LDPC Codes Based on Reciprocal Channel Approximation.” 2022 IEEE International Symposium on Information Theory (ISIT). IEEE, 2022.

FIGS. 1-4 below describe various embodiments implemented in wireless communications systems and with the use of orthogonal frequency division multiplexing (OFDM) or orthogonal frequency division multiple access (OFDMA) communication techniques. The descriptions of FIGS. 1-4 are not meant to imply physical or architectural limitations to how different embodiments may be implemented. Different embodiments of the present disclosure may be implemented in any suitably arranged communications system.

FIG. 1 illustrates an example wireless network 100 within which LDPC decoding may be implemented according to embodiments of the present disclosure. The embodiment of the wireless network 100 shown in FIG. 1 is for illustration only. Other embodiments of the wireless network 100 could be used without departing from the scope of this disclosure.

As shown in FIG. 1, the wireless network 100 includes a gNB 101 (e.g., base station, BS), a gNB 102, and a gNB 103. The gNB 101 communicates with the gNB 102 and the gNB 103. The gNB 101 also communicates with at least one network 130, such as the Internet, a proprietary Internet Protocol (IP) network, or other data network.

The gNB 102 provides wireless broadband access to the network 130 for a first plurality of user equipments (UEs) within a coverage area 120 of the gNB 102. The first plurality of UEs includes a UE 111, which may be located in a small business; a UE 112, which may be located in an enterprise; a UE 113, which may be a WiFi hotspot; a UE 114, which may be located in a first residence; a UE 115, which may be located in a second residence; and a UE 116, which may be a mobile device, such as a cell phone, a wireless laptop, a wireless PDA, or the like. The gNB 103 provides wireless broadband access to the network 130 for a second plurality of UEs within a coverage area 125 of the gNB 103. The second plurality of UEs includes the UE 115 and the UE 116. In some embodiments, one or more of the gNBs 101-103 may communicate with each other and with the UEs 111-116 using 5G/NR, long term evolution (LTE), long term evolution-advanced (LTE-A), WiMAX, WiFi, or other wireless communication techniques.

Depending on the network type, the term “base station” or “BS” can refer to any component (or collection of components) configured to provide wireless access to a network, such as transmit point (TP), transmit-receive point (TRP), an enhanced base station (eNodeB or eNB), a 5G/NR base station (gNB), a macrocell, a femtocell, a WiFi access point (AP), or other wirelessly enabled devices. Base stations may provide wireless access in accordance with one or more wireless communication protocols, e.g., 5G/NR 3^{rd} generation partnership project (3GPP) NR, long term evolution (LTE), LTE advanced (LTE-A), high speed packet access (HSPA), Wi-Fi 802.11a/b/g/n/ac, etc. For the sake of convenience, the terms “BS” and “TRP” are used interchangeably in this patent document to refer to network infrastructure components that provide wireless access to remote terminals. Also, depending on the network type, the term “user equipment” or “UE” can refer to any component such as “mobile station,” “subscriber station,” “remote terminal,” “wireless terminal,” “receive point,” or “user device.” For the sake of convenience, the terms “user equipment” and “UE” are used in this patent document to refer to remote wireless equipment that wirelessly accesses a BS, whether the UE is a mobile device (such as a mobile telephone or smartphone) or is normally considered a stationary device (such as a desktop computer or vending machine).

The dotted lines show the approximate extents of the coverage areas 120 and 125, which are shown as approximately circular for the purposes of illustration and explanation only. It should be clearly understood that the coverage areas associated with gNBs, such as the coverage areas 120 and 125, may have other shapes, including irregular shapes, depending upon the configuration of the gNBs and variations in the radio environment associated with natural and man-made obstructions.

As described in more detail below, one or more of the UEs 111-116 include circuitry, programing, or a combination thereof for decoding of low-density parity check codes. In certain embodiments, one or more of the BSs 101-103 include circuitry, programing, or a combination thereof to support LDPC decoding.

Although FIG. 1 illustrates one example of a wireless network, various changes may be made to FIG. 1. For example, the wireless network 100 could include any number of gNBs and any number of UEs in any suitable arrangement. Also, the gNB 101 could communicate directly with any number of UEs and provide those UEs with wireless broadband access to the network 130. Similarly, each gNB 102-103 could communicate directly with the network 130 and provide UEs with direct wireless broadband access to the network 130. Further, the gNBs 101, 102, and/or 103 could provide access to other or additional external networks, such as external telephone networks or other types of data networks.

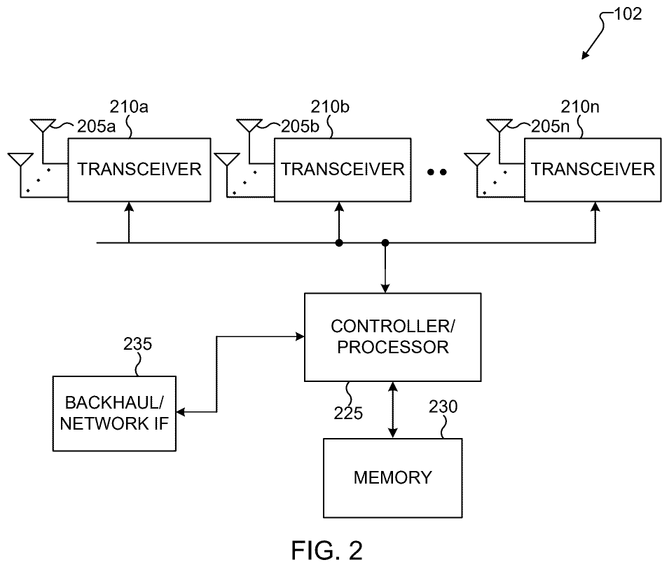

FIG. 2 illustrates an example gNB 102 within which LDPC decoding may be implemented according to embodiments of the present disclosure. The embodiment of the gNB 102 illustrated in FIG. 2 is for illustration only, and the gNBs 101 and 103 of FIG. 1 could have the same or similar configuration. However, gNBs come in a wide variety of configurations, and FIG. 2 does not limit the scope of this disclosure to any particular implementation of a gNB.

As shown in FIG. 2, the gNB 102 includes multiple antennas 205a-205n, multiple transceivers 210a-210n, a controller/processor 225, a memory 230, and a backhaul or network interface 235.

The transceivers 210a-210n receive, from the antennas 205a-205n, incoming radio frequency (RF) signals, such as signals transmitted by UEs in the wireless network 100. The transceivers 210a-210n down-convert the incoming RF signals to generate IF or baseband signals. The IF or baseband signals are processed by receive (RX) processing circuitry in the transceivers 210a-210n and/or controller/processor 225, which generates processed baseband signals by filtering, decoding, and/or digitizing the baseband or IF signals. The controller/processor 225 may further process the baseband signals.

Transmit (TX) processing circuitry in the transceivers 210a-210n and/or controller/processor 225 receives analog or digital data (such as voice data, web data, e-mail, or interactive video game data) from the controller/processor 225. The TX processing circuitry encodes, multiplexes, and/or digitizes the outgoing baseband data to generate processed baseband or IF signals. The transceivers 210a-210n up-converts the baseband or IF signals to RF signals that are transmitted via the antennas 205a-205n.

The controller/processor 225 can include one or more processors or other processing devices that control the overall operation of the gNB 102. For example, the controller/processor 225 could control the reception of uplink (UL) channel signals and the transmission of downlink (DL) channel signals by the transceivers 210a-210n in accordance with well-known principles. The controller/processor 225 could support additional functions as well, such as more advanced wireless communication functions. For instance, the controller/processor 225 could support beam forming or directional routing operations in which outgoing/incoming signals from/to multiple antennas 205a-205n are weighted differently to effectively steer the outgoing signals in a desired direction. As another example, the controller/processor 225 could support methods for beam management in JPTA system with multiple component carriers. Any of a wide variety of other functions could be supported in the gNB 102 by the controller/processor 225.

The controller/processor 225 is also capable of executing programs and other processes resident in the memory 230, such as processes to trigger beam management in JPTA system with multiple component carriers. The controller/processor 225 can move data into or out of the memory 230 as required by an executing process.

The controller/processor 225 is also coupled to the backhaul or network interface 235. The backhaul or network interface 235 allows the gNB 102 to communicate with other devices or systems over a backhaul connection or over a network. The interface 235 could support communications over any suitable wired or wireless connection(s). For example, when the gNB 102 is implemented as part of a cellular communication system (such as one supporting 5G/NR, LTE, or LTE-A), the interface 235 could allow the gNB 102 to communicate with other gNBs over a wired or wireless backhaul connection. When the gNB 102 is implemented as an access point, the interface 235 could allow the gNB 102 to communicate over a wired or wireless local area network or over a wired or wireless connection to a larger network (such as the Internet). The interface 235 includes any suitable structure supporting communications over a wired or wireless connection, such as an Ethernet or transceiver.

The memory 230 is coupled to the controller/processor 225. Part of the memory 230 could include a RAM, and another part of the memory 230 could include a Flash memory or other ROM.

Although FIG. 2 illustrates one example of gNB 102, various changes may be made to FIG. 2. For example, the gNB 102 could include any number of each component shown in FIG. 2. Also, various components in FIG. 2 could be combined, further subdivided, or omitted and additional components could be added according to particular needs.

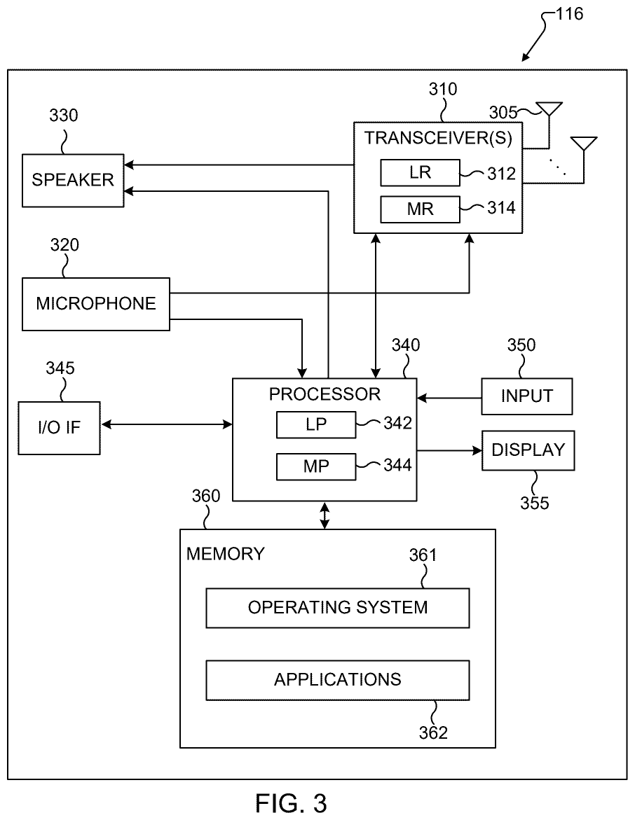

FIG. 3 illustrates an example UE 116 within which decoding of low-density parity check codes may be implemented according to embodiments of the present disclosure. The embodiment of the UE 116 illustrated in FIG. 3 is for illustration only, and the UEs 111-115 of FIG. 1 could have the same or similar configuration. However, UEs come in a wide variety of configurations, and FIG. 3 does not limit the scope of this disclosure to any particular implementation of a UE.

As shown in FIG. 3, the UE 116 includes antenna(s) 305, a transceiver(s) 310, and a microphone 320. The UE 116 also includes a speaker 330, a processor 340, an input/output (I/O) interface (IF) 345, an input 350, a display 355, and a memory 360. The memory 360 includes an operating system (OS) 361 and one or more applications 362.

The transceiver(s) 310 receives from the antenna(s) 305, an incoming RF signal transmitted by a gNB of the wireless network 100. The transceiver(s) 310 down-converts the incoming RF signal to generate an intermediate frequency (IF) or baseband signal. The IF or baseband signal is processed by RX processing circuitry in the transceiver(s) 310 and/or processor 340, which generates a processed baseband signal by filtering, decoding, and/or digitizing the baseband or IF signal. The RX processing circuitry sends the processed baseband signal to the speaker 330 (such as for voice data) or is processed by the processor 340 (such as for web browsing data).

TX processing circuitry in the transceiver(s) 310 and/or processor 340 receives analog or digital voice data from the microphone 320 or other outgoing baseband data (such as web data, e-mail, or interactive video game data) from the processor 340. The TX processing circuitry encodes, multiplexes, and/or digitizes the outgoing baseband data to generate a processed baseband or IF signal. The transceiver(s) 310 up-converts the baseband or IF signal to an RF signal that is transmitted via the antenna(s) 305.

The processor 340 can include one or more processors or other processing devices and execute the OS 361 stored in the memory 360 in order to control the overall operation of the UE 116. For example, the processor 340 could control the reception of DL channel signals and the transmission of UL channel signals by the transceiver(s) 310 in accordance with well-known principles. In some embodiments, the processor 340 includes at least one microprocessor or microcontroller.

The processor 340 is also capable of executing other processes and programs resident in the memory 360. For example, the processor 340 may execute processes for beam management in JPTA system with multiple component carriers as described in embodiments of the present disclosure. The processor 340 can move data into or out of the memory 360 as required by an executing process. In some embodiments, the processor 340 is configured to execute the applications 362 based on the OS 361 or in response to signals received from gNBs or an operator. The processor 340 is also coupled to the I/O interface 345, which provides the UE 116 with the ability to connect to other devices, such as laptop computers and handheld computers. The I/O interface 345 is the communication path between these accessories and the processor 340.

The processor 340 is also coupled to the input 350, which includes, for example, a touchscreen, keypad, etc., and the display 355. The operator of the UE 116 can use the input 350 to enter data into the UE 116. The display 355 may be a liquid crystal display, light emitting diode display, or other display capable of rendering text and/or at least limited graphics, such as from web sites.

The memory 360 is coupled to the processor 340. Part of the memory 360 could include a random-access memory (RAM), and another part of the memory 360 could include a Flash memory or other read-only memory (ROM).

Although FIG. 3 illustrates one example of UE 116, various changes may be made to FIG. 3. For example, various components in FIG. 3 could be combined, further subdivided, or omitted and additional components could be added according to particular needs. As a particular example, the processor 340 could be divided into multiple processors, such as one or more central processing units (CPUs) and one or more graphics processing units (GPUs). In another example, the transceiver(s) 310 may include any number of transceivers and signal processing chains and may be connected to any number of antennas. Also, while FIG. 3 illustrates the UE 116 configured as a mobile telephone or smartphone, UEs could be configured to operate as other types of mobile or stationary devices.

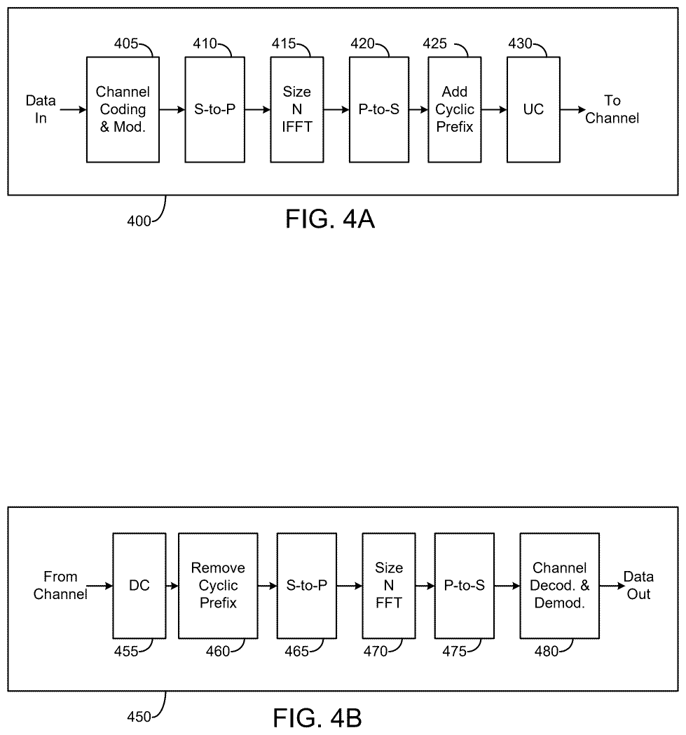

FIG. 4A and FIG. 4B illustrate an example of wireless transmit and receive paths 400 and 450, respectively, according to embodiments of the present disclosure. For example, a transmit path 400 may be described as being implemented in a gNB (such as gNB 102), while a receive path 450 may be described as being implemented in a UE (such as UE 116). However, it will be understood that the receive path 450 can be implemented in a gNB and that the transmit path 400 can be implemented in a UE. In some embodiments, the receive path 450 is configured for decoding of low-density parity check codes as described in embodiments of the present disclosure. For example, embodiments of LDPC decoding as described herein may be implemented in connection with channel decoding and demodulation 480 depicted in FIG. 4B.

As illustrated in FIG. 4A, the transmit path 400 includes a channel coding and modulation block 405, a serial-to-parallel (S-to-P) block 410, a size N Inverse Fast Fourier Transform (IFFT) block 415, a parallel-to-serial (P-to-S) block 420, an add cyclic prefix block 425, and an up-converter (UC) 430. The receive path 450 includes a down-converter (DC) 455, a remove cyclic prefix block 460, a S-to-P block 465, a size N Fast Fourier Transform (FFT) block 470, a parallel-to-serial (P-to-S) block 475, and a channel decoding and demodulation block 480.

In the transmit path 400, the channel coding and modulation block 405 receives a set of information bits, applies coding (such as a low-density parity check (LDPC) coding), and modulates the input bits (such as with Quadrature Phase Shift Keying (QPSK) or Quadrature Amplitude Modulation (QAM)) to generate a sequence of frequency-domain modulation symbols. The serial-to-parallel block 410 converts (such as de-multiplexes) the serial modulated symbols to parallel data in order to generate N parallel symbol streams, where N is the IFFT/FFT size used in the gNB 102 and the UE 116. The size N IFFT block 415 performs an IFFT operation on the N parallel symbol streams to generate time-domain output signals. The parallel-to-serial block 420 converts (such as multiplexes) the parallel time-domain output symbols from the size N IFFT block 415 in order to generate a serial time-domain signal. The add cyclic prefix block 425 inserts a cyclic prefix to the time-domain signal. The up-converter 430 modulates (such as up-converts) the output of the add cyclic prefix block 425 to a RF frequency for transmission via a wireless channel. The signal may also be filtered at a baseband before conversion to the RF frequency.

As illustrated in FIG. 4B, the down-converter 455 down-converts the received signal to a baseband frequency, and the remove cyclic prefix block 460 removes the cyclic prefix to generate a serial time-domain baseband signal. The serial-to-parallel block 465 converts the time-domain baseband signal to parallel time-domain signals. The size N FFT block 470 performs an FFT algorithm to generate N parallel frequency-domain signals. The (P-to-S) block 475 converts the parallel frequency-domain signals to a sequence of modulated data symbols. The channel decoding and demodulation block 480 demodulates and decodes the modulated symbols to recover the original input data stream.

Each of the gNBs 101-103 may implement a transmit path 400 that is analogous to transmitting in the downlink to UEs 111-116 and may implement a receive path 450 that is analogous to receiving in the uplink from UEs 111-116. Similarly, each of UEs 111-116 may implement a transmit path 400 for transmitting in the uplink to gNBs 101-103 and may implement a receive path 450 for receiving in the downlink from gNBs 101-103.

Each of the components in FIGS. 4A and 4B can be implemented using only hardware or using a combination of hardware and software/firmware. As a particular example, at least some of the components in FIGS. 4A and 4B may be implemented in software, while other components may be implemented by configurable hardware or a mixture of software and configurable hardware. For instance, the FFT block 470 and the IFFT block 415 may be implemented as configurable software algorithms, where the value of size N may be modified according to the implementation.

Furthermore, although described as using FFT and IFFT, this is by way of illustration only and should not be construed to limit the scope of the present disclosure. Other types of transforms, such as Discrete Fourier Transform (DFT) and Inverse Discrete Fourier Transform (IDFT) functions, can be used. It will be appreciated that the value of the variable N may be any integer number (such as 1, 2, 3, 4, or the like) for DFT and IDFT functions, while the value of the variable N may be any integer number that is a power of two (such as 1, 2, 4, 8, 16, or the like) for FFT and IFFT functions.

Although FIGS. 4A and 4B illustrate examples of wireless transmit and receive paths 400 and 450, respectively, various changes may be made to FIGS. 4A and 4B. For example, various components in FIGS. 4A and 4B can be combined, further subdivided, or omitted and additional components can be added according to particular needs. Also, FIGS. 4A and 4B are meant to illustrate examples of the types of transmit and receive paths that can be used in a wireless network. Any other suitable architectures can be used to support wireless communications in a wireless network.

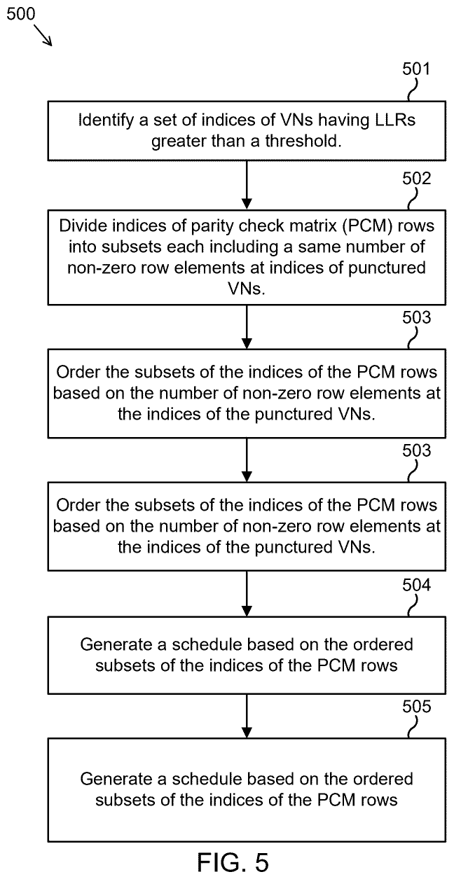

FIG. 5 illustrates a flowchart of an example procedure 500 for LDPC decoding according to embodiments of the present disclosure. For example, procedure 500 for decoding of low-density parity check codes can be performed by the UE 116, the gNB 102, and/or network 130 in the wireless network 100 of FIG. 1. This example is for illustration only and other embodiments can be used without departing from the scope of the present disclosure.

The procedure 500 begins with identifying a set of indices of variable nodes (VNs) having log-likelihood ratios (LLRs) greater than a threshold (step 501). Channel observations may be used to determine VNs exceeding the threshold. Indices of parity check matrix (PCM) rows are divided into subsets, with each subset including a same number of non-zero row elements at indices of punctured VNs (step 502). For example, the PCM rows may be ordered in ascending number of the non-zero row elements at the indices of the punctured VNs. The subsets of the indices of the PCM rows are ordered based on the number of non-zero row elements at the indices of the punctured VNs (step 503). Row weight, excluding row elements at the indices of the VNs, may be employed for sorting the subset of PCM row indices. A schedule is generated based on the ordered subsets of the indices of the PCM rows (step 504), and layered LDPC decoding is performed according to the schedule (step 505).

Although FIG. 5 illustrates one example of a process 500 for LDPC decoding, various changes may be made to FIG. 5. For example, while shown as a series of steps, various steps in FIG. 5 could overlap, occur in parallel, occur in a different order, or occur any number of times (including zero times).

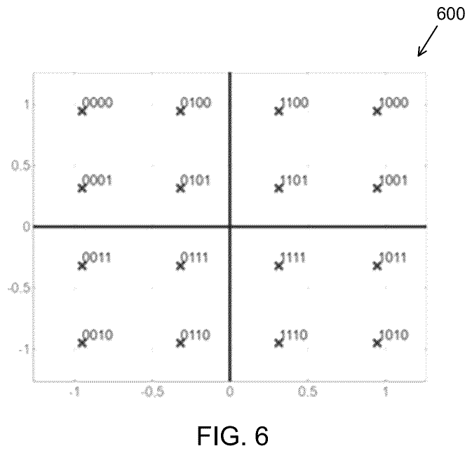

FIG. 6 illustrates a diagram of an example 600 of a constellation and labeling rule of modulation for use with decoding of low-density parity check codes according to embodiments of the present disclosure. For example, the example 600 can be implemented by any of the UEs 111-116 of FIG. 1, such as the UE 111. This example is for illustration only and other embodiments can be used without departing from the scope of the present disclosure.

In communication systems, modulation is an essential technique used to improve spectral efficiency. Modulation is defined by the example 600 with a one-to-one labeling function which maps m bits {bₗ:l=0,1, . . . , m−1} to a constellation comprising 2^{m} symbols. Bₗ represents the random variable version of bₗ. For example, FIG. 6 illustrates an example of quadrature amplitude modulation (QAM) with constellation size 16 and Gray labeling according to an embodiment of the disclosure. In the sequel, bit level l∈{0,1, . . . , m−1} represents the position of lth bit in the labeling.

Although FIG. 6 illustrates one example of a constellation and labeling rule for use in LDPC decoding, various changes may be made to FIG. 6. For example, while FIG. 6 shows each symbol as represented with four bits (i.e., QAM16), six bits per symbol (QAM64) or eight bits per symbol (QAM256) may be employed instead.

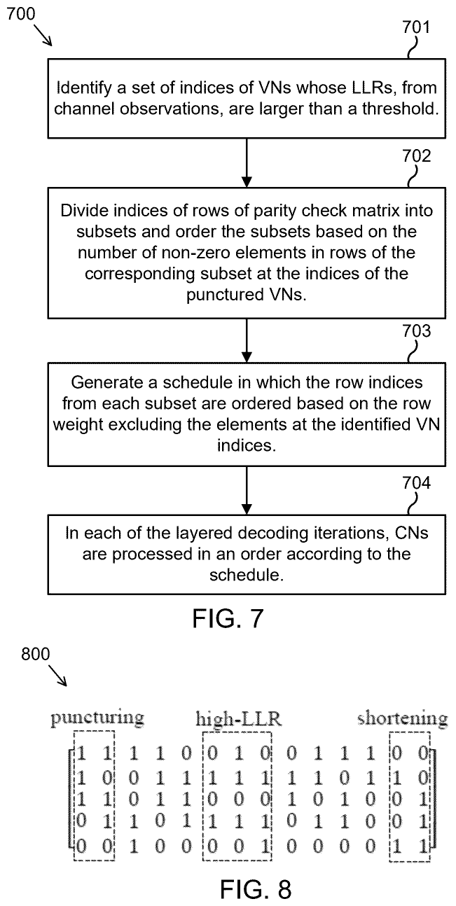

FIG. 7 is a flowchart of an example procedure 700 for LDPC decoding according to embodiments of the present disclosure. For example, the procedure 700 for decoding of low-density parity check codes can be performed by the UE 116, the gNB 102, and/or network 130 in the wireless network 100 of FIG. 1. This example is for illustration only and other embodiments can be used without departing from the scope of the present disclosure.

In the layered decoding, a schedule which is defined as a permuted version of row indices [0:N−K−1] determines the order of processing CNs.

In LDPC codes, there may exist shortening VNs whose corresponding bits are fixed to zeros and indices are known by the decoder. The bits corresponding to the shortening VNs may not be transmitted and their LLRs can be initialized to infinity for decoding. Let [symbol] ₀ denote the set of indices of shortening VNs. There may exist punctured VNs whose corresponding bits may not be transmitted and their LLRs can be initialized to zeros for decoding. Denote P the number of punctured VNs and [symbol] the set of indices of punctured VNs.

FIG. 8 illustrates an example 800 of a parity check matrix of LDPC codes for use with LDPC decoding according to embodiments of the present disclosure. This example is for illustration only and other embodiments can be used without departing from the scope of the present disclosure.

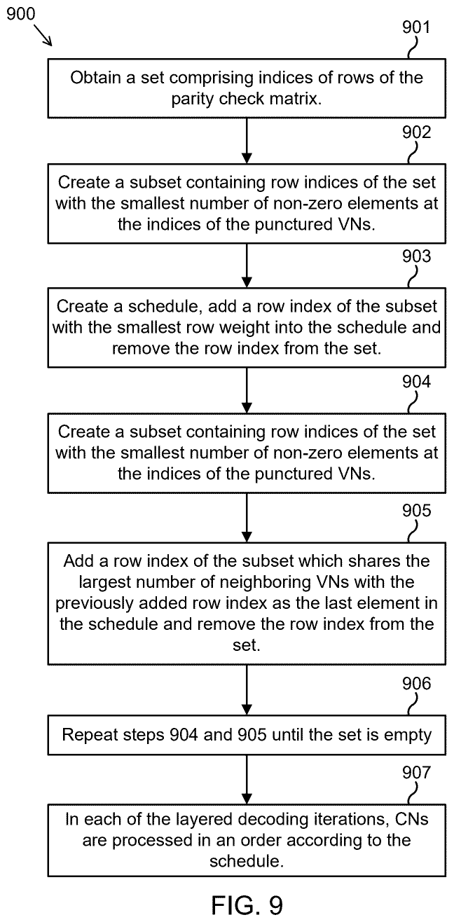

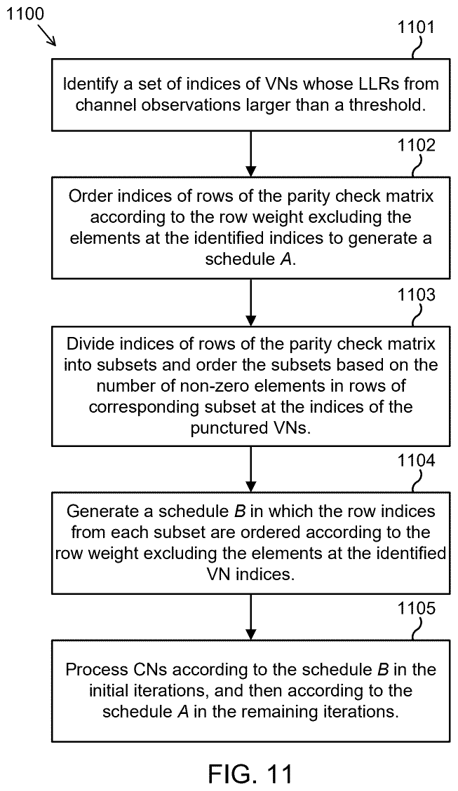

The example parity check matrix 800 of LDPC codes with five CNs/rows and fourteen VNs/columns. In this example, columns v₀ and v₁ are punctured and hence P=2 and [symbol] ={0,1}. In addition, columns v₁₂ and v₁₃ are shortened and hence [symbol] ₀={12,13}. The example parity check matrix 800 of FIG. 8 is used to illustrate aspects of the process 700 depicted in FIG. 7, the process 900 of FIG. 9, and the process 1100 of FIG. 11.

Referring back to FIG. 7, the process 700 begins with identifying a set of indices of VNs whose corresponding LLRs, calculated based on channel observations, have amplitudes larger than a threshold (step 701). The identified indices form a set [symbol] ₁. One embodiment for generating [symbol] ₁ is described below. In the example parity check matrix of FIG. 8, columns v₅, v₆ and v₇ are assigned with LLRs of high amplitudes and hence [symbol] ₁={5, 6, 7}.

Denote h a vector. In the sequel, let [symbol] denote a sub-vector of h that is composed of the elements of h at indices belonging to the set [symbol] . In the example parity check matrix of FIG. 8, h₀ represents the row 0 of the parity check matrix and [symbol] ={1,1}. Let w(h) denote the weight of a vector h which is defined to be the number of non-zero elements of h. In the example parity check matrix of FIG. 8, w(h₀)=8 and w(h_{0,} [symbol] )=2.

Indices of rows of PCM are divided into subsets (step 702), each of which contains the indices of rows with the same number of non-zero elements at the indices of the punctured VNs. Let ϕ^{(p)} [symbol] {j:w( [symbol] )=p} denote the subset of the row indices whose corresponding rows have p∈{0,1, . . . , P} non-zero elements at the indices belonging to [symbol] . Then, the subsets {ϕ^{(p)}:p=0,1, . . . , P} are sorted in an ascending order of the number of non-zero elements of rows at the indices of the punctured VNs, which results in the set of indices shown as ϕ={ϕ⁽⁰⁾, ϕ⁽¹⁾, . . . , ϕ^{(P)}}. Due to the ordering of the subsets of row indices, the layer decoder can first process the CNs which are connected to smaller number of the punctured VNs. In the example parity check matrix of FIG. 8, row indices {0, 1, 2, 3, 4} are divided into 3 subsets, where the subset ϕ⁽⁰⁾={4} corresponds to the row 4 with two zeros at the punctured indices [symbol] ={0,1}, the subset ϕ⁽¹⁾={1,3} corresponds to the row 1 and the row 3 with one non-zero element at the punctured indices [symbol] ={0,1} and the subset ϕ⁽²⁾={0,2} corresponds to the row 0 and the row 2 with two non-zero elements at the punctured indices [symbol] ={0,1}. By ordering these three subsets in an ascending order of p, the resulting set of indices is shown as ϕ={{4}, {1,3}, . . . , {0,2}}.

The schedule \tilde{ϕ}={\tilde{ϕ}⁽⁰⁾, . . . , \tilde{ϕ}^{(p)}, . . . , \tilde{ϕ}^{(P)}} is generated (step 703), where \tilde{ϕ}^{(p)} is obtained by ordering the row indices from subset ϕ^{(p)} in an ascending order based on the row weight without considering the elements at the indices of the shortening VNs and the identified indices. Therefore, given

$${\tilde{ϕ}}_{i}^{( p )} and {\tilde{ϕ}}_{j}^{( p )}$$

which are respectively i-th and j-th element in \tilde{ϕ}^{(p)} with i<j,

$$w ( {h}_{{\tilde{ϕ}}_{i}^{( p )} , [ 0 : N - 1 ] \backslash \{ {𝒮}_{0} , {𝒮}_{1} \}} ) \leq w ( {h}_{{\tilde{ϕ}}_{j}^{( p )} , [ 0 : N - 1 ] \backslash \{ {𝒮}_{0} ⋃ {𝒮}_{1} \}} ) ,$$

where [0:N−1]\{ [symbol] ₀∪ [symbol] ₁} denotes the set of indices [0:N−1]={0,1, . . . , N−1} excluding the indices belonging to [symbol] ₀ or [symbol] ₁. For the sake of simplicity, \tilde{ϕ}={\tilde{ϕ}₀, \tilde{ϕ}₁, . . . , \tilde{ϕ}_{N-K-1}}. In the example parity check matrix of FIG. 8, since the shortening VN indices are [symbol] ₀={12,13} and the high-LLR VN indices are [symbol] ₁={5,6,7}, the ordering of the row indices within the subsets ϕ⁽¹⁾={1,3} and ϕ⁽²⁾={0,2} is based on the corresponding row elements at indices [0:13]\{{12,13}∪{5,6,7}}={0,1,2,3,4,8,9,10,11}. Within the subset ϕ⁽¹⁾= {1,3}, since w(h_{3,{0,1,2,3,4,8,9,10,11}})=5<w(h_{1,{0,1,2,3,4,8,9,10,11}})=6, \tilde{ϕ}⁽¹⁾={3,1} is obtained. Within the subset ϕ⁽²⁾={0,2}, since w(h_{2,{0,1,2,3,4,8,9,10,11}})=6<w(h_{0,{0,1,2,3,4,8,9,10,11}})=7, \tilde{ϕ}⁽²⁾={2,0} is obtained. In addition, \tilde{ϕ}⁽⁰⁾=\tilde{ϕ}⁽⁰⁾={4}. Therefore, the resulting schedule is \tilde{ϕ}={\tilde{ϕ}⁽⁰⁾, \tilde{ϕ}⁽¹⁾, \tilde{ϕ}⁽²⁾}={4,3,1,2,0}.

Let [symbol] ⱼ and [symbol] ᵢ denote the set of indices of VNs connected to CN j and the set of indices of CNs connected to VN i, respectively. [symbol] _{j\i} and [symbol] _{i\j} denote [symbol] ⱼ excluding VN index i and [symbol] ᵢ excluding CN index j, respectively. α_{i→j} and β_{j→i} denote V2C message passed from VN i to CN j and C2V message passed from CN j to VN i, respectively. γᵢ denotes a posteriori LLR for VN vᵢ. β_{j→i} is initialized to zeros. γᵢ is initialized to +∞ for the shortening VNs, zeros for the punctured VNs and LLRs from channel observations for the remaining VNs.

Within each iteration of the layered decoding (step 704), the CNs are processed from CN \tilde{ϕ}₀ to CN \tilde{ϕ}_{N-K-1} sequentially. When processing CN \tilde{ϕ}ⱼ, V2C LLRs for VNs connected to the CN \tilde{ϕ}ⱼ are updated as follows:

$${α}_{i \to {\tilde{ϕ}}_{j}} ← {γ}_{i} - {β}_{{\tilde{ϕ}}_{j} \to i} for i ∈ {𝒱}_{{\tilde{ϕ}}_{j} .} \qquad ( 1 )$$

Then, C2V LLR and a posteriori LLR are updated for a VN if it is connected to the CN \tilde{ϕ}ⱼ. The updates are shown as follows:

$${β}_{{\tilde{ϕ}}_{j} \to i} ← {\prod }_{{i}^{′} ∈ {𝒱}_{{\tilde{ϕ}}_{j \backslash i}}} sgn ( {α}_{{i}^{′} \to {\tilde{ϕ}}_{j}} ) \times f ( \{ \vert {α}_{{i}^{′} \to {\tilde{ϕ}}_{j}} \vert : {i}^{′} ∈ {𝒱}_{{\tilde{ϕ}}_{j \backslash i}} \} ) , \qquad ( 2 )$$

$$and$$

$${γ}_{i} ← {α}_{i \to {\tilde{ϕ}}_{j}} + {β}_{{\tilde{ϕ}}_{j} \to i} , \qquad ( 3 )$$

for i∈ [symbol] _{\tilde{ϕ}}_{ⱼ}. In Equation (2), sgn(·) returns the sign of a value and the function ƒ(·) depends on the method used to calculate C2V LLR, e.g., in min-sum algorithm

$$f ( \{ \vert {α}_{i \to {\tilde{ϕ}}_{j}} \vert : {i}^{′} ∈ {𝒱}_{{α}_{{\tilde{ϕ}}_{j \backslash i}}} \} ) = {min}_{{i}^{′} ∈ {𝒱}_{{α}_{{\tilde{ϕ}}_{j \backslash i}}}} \vert {α}_{i \to {\tilde{ϕ}}_{j}} \vert .$$

The updated γᵢ and β_{\tilde{ϕ}}_{ⱼ}_{→i} can be employed in processing next CN \tilde{ϕ}ⱼ₊₁.

Although FIG. 7 illustrates one example of a process 700 for LDPC decoding, various changes may be made to FIG. 7. For example, while shown as a series of steps, various steps in FIG. 7 could overlap, occur in parallel, occur in a different order, or occur any number of times (including zero times).

FIG. 9 is a flowchart of an example procedure 900 for layered decoding according to embodiments of the present disclosure. For example, the procedure 900 for layered decoding can be performed by the UE 116, the gNB 102, and/or network 130 in the wireless network 100 of FIG. 1, as part of the procedure 700 depicted in FIG. 7. This example is for illustration only and other embodiments can be used without departing from the scope of the present disclosure.

A set [symbol] =[0:N−K−1] comprising indices of rows of the parity check matrix is obtained (step 901). A subset [symbol] containing row indices of the set [symbol] with the smallest number of non-zero elements at the indices of the punctured VNs is generated (step 902). Let

$${d}_{min} {= min}_{j ∈ 𝒜} w ( {h}_{j , 𝒫} )$$

denote the smallest number of non-zero elements at the indices of the punctured VNs. The subset is shown as [symbol] ={j∈ [symbol] :w( [symbol] )=dₘᵢₙ}.

A schedule \tilde{ϕ} is created and initialized to an empty set (step 903). A row index of the subset with the smallest row weight, i.e.,

$${\tilde{ϕ}}_{0} = arg {min}_{j ∈ ℬ} w ( {h}_{j , [ ] 0 : N - 1 ]} ) ,$$

is added into the schedule and removed from the set. Hence, the schedule and the set become \tilde{ϕ}={\tilde{ϕ}₀} and [symbol] = [symbol] \\tilde{ϕ}₀, respectively. More than one index of the subset with the smallest row weight may exist, in which case one of them can be randomly selected to be \tilde{ϕ}₀.

Step 902 is repeated to generate a new subset [symbol] based on the latest set [symbol] (step 904).

In order to immediately utilize the latest messages from the previous CN to process the current CN, the two CNs should share the neighboring VNs as much as possible. The number of neighbors shared by CN j₁ and CN j₂ can be measured by w(hⱼ_{₁}_{,[0:N-1]}& hⱼ_{₂}_{,[0:N-1}]), where “&” represents the bitwise “AND” operation.

A row index of the subset which shares the largest number of neighboring VNs with the previously added row index is added as the last element in the schedule (step 905). Given that \tilde{ϕ}={\tilde{ϕ}₀, \tilde{ϕ}₍₁₎, . . . , \tilde{ϕ}ⱼ₋₁} has been decided where \tilde{ϕ}ⱼ₋₁ represents the previously added row index,

$${\tilde{ϕ}}_{j} = arg {max}_{{j}^{′} ∈ ℬ} w ( {h}_{{j}^{′} , [ 0 : N - 1 ]} \& {h}_{{\tilde{ϕ}}_{j - 1} , [ 0 : N - 1 ]} )$$

is added as the last element of the schedule and the schedule becomes \tilde{ϕ}={\tilde{ϕ}₀, \tilde{ϕ}₍₁₎, . . . , \tilde{ϕ}ⱼ₋₁, \tilde{ϕ}ⱼ}. In addition, \tilde{ϕ}ⱼ is removed from the set [symbol] , i.e., [symbol] = [symbol] \\tilde{ϕ}ⱼ. More than one row index may share the largest number of neighboring VNs with the previously added row index, in which case one of them can be randomly selected to be \tilde{ϕ}ⱼ.

Steps 904 and 905 are repeated to add elements one-by-one into the schedule until the set [symbol] becomes empty (step 906).

In the example parity check matrix of FIG. 8, the indices of the punctured VNs are [symbol] ={0,1} and the number of non-zero elements of rows at the indices [symbol] ={0,1} are respectively w(h_{0,{0,1}})=2, w(h_{1,{0,1}})=1, w(h_{2,{0,1}})=2, w(h_{3,{0,1}})=1 and w (h_{4,{0,1}})=0. According to steps 901 through 906, the corresponding schedule is generated as follows:
1. According to step 901: [symbol] ={0,1,2,3,4}.
2. According to step 902: The subset [symbol] ={4} because w(h_{4,{0,1}})=0<w(h_{1,{0,1}})=w(h_{3,{0,1}})=1<w(h_{0,{0,1}})=w(h_{2,{0,1}})=2.
3. According to step 903: \tilde{ϕ}₀=4 which is the only element in the subset [symbol] ={4} is added into the schedule and removed from the set. Hence, the schedule and the set become \tilde{ϕ}={4} and [symbol] ={0,1,2,3}, respectively.
4. According to step 904: The subset [symbol] ={1,3} because w(h_{1,{0,1}})=w(h_{3,{0,1}})=1<w(h_{0,{0,1}})=w(h_{2,{0,1}})=2.
5. According to step 905: Because the previously added row index is 4 and w(h_{3,{0:13}}& h_{4,[0:13]})=3>w(h_{1,{0:13}}& h_{4,{0:13}})=2, \tilde{ϕ}₁=3 is added as the last element of the schedule and removed from the set [symbol] . Hence, the schedule and the set become \tilde{ϕ}={4,3} and [symbol] ={0,1,2}, respectively.
6. According to step 906: steps 905 and 905 are repeated.
7. According to step 904: The subset [symbol] ={1} because w(h_{1,{0,1}})=1<w(h_{0,{0,1}})=w(h_{2,{0,1}})=2.
8. According to step 905: \tilde{ϕ}₂=1 is added as the last element of the schedule and removed from the set. Hence, the schedule and the set become \tilde{ϕ}={4,3,1} and [symbol] ={0,2}, respectively.
9. According to step 906: steps 905 and 905 are repeated.
10. According to step 904: The subset [symbol] ={0,2} because w(h_{0,{0,1}})=w(h_{2,{0,1}})=2.
11. According to step 905: Because the previously added row index is 1 and w(h_{0,{0:13}}& h_{1,{0:13}})=5>w(h_{2,{0:13}}& h_{1,{0:13}})=4, \tilde{ϕ}₃=0 is added as the last element of the schedule and removed from the set. Hence, the schedule and the set become \tilde{ϕ}={4,3,1,0 } and [symbol] ={2}, respectively.
12. According to step 906: steps 905 and 905 are repeated. Because only one element left in the set [symbol] ={2}, \tilde{ϕ}₄=2 is added as the last element of the schedule and removed from the set [symbol] . Hence, the resulting schedule is \tilde{ϕ}={4,3,1,0,2} and the set becomes [symbol] ={ }.
13. According to step 906: step 907 is performed
   Within each iteration of the layered decoding (step 907), the CNs are processed from CN \tilde{ϕ}₀ to CN \tilde{ϕ}_{N-K-1} sequentially to update messages based on Equations (1)-(3).

Although FIG. 9 illustrates one example of a process 900 for layered decoding, various changes may be made to FIG. 9. For example, while shown as a series of steps, various steps in FIG. 9 could overlap, occur in parallel, occur in a different order, or occur any number of times (including zero times).

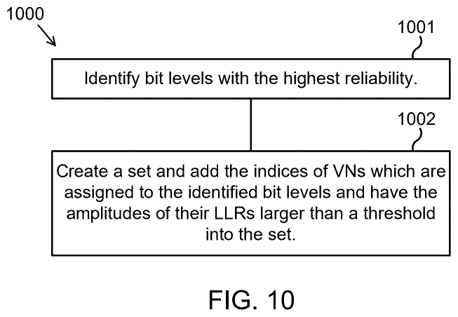

FIG. 10 is a flowchart of an example procedure 1000 for identifying a set of indices of variable nodes according to embodiments of the present disclosure. For example, the procedure 1000 for identifying a set of indices of variable nodes can be performed by the UE 116, the gNB 102, and/or network 130 in the wireless network 100 of FIG. 1, as part of the procedure 700 depicted in FIG. 7. This example is for illustration only and other embodiments can be used without departing from the scope of the present disclosure.

Without loss of generality, it is assumed that codeword bit vᵢ of LDPC codes is assigned to bit level l=(i mod m) in modulation with constellation size 2^{m}.

The bit levels with the highest reliability are identified and the indices of the identified bit levels form a set [symbol] (step 1001). In an embodiment, the reliability of a bit level can be measured by the mutual information between Bₗ and the received signal Y, denoted I(Bₗ, Y). The larger the mutual information is, the more reliable the bit level is. For example, in 16-QAM shown in FIG. 6, I(B₀, Y)=I(B₂, Y)>I(B₁, Y)=I(B₃, Y) and therefore the bit levels [symbol] ={0,2} can be identified. In another embodiment, the reliability of bit level l can be measured by the bit error rate

$${P}_{e}^{( l )} .$$

The lower the bit rate is, the more reliable the bit level is.

$${P}_{e}^{( l )}$$

can be obtained as follow.
Let λ^{(l)} and s denote the LLR of bₗ and signal-to-noise ratio (SNR), respectively. Based on λ^{(l)}, a bit 0 is recovered if λ^{(l)}≥0, otherwise a bit 1 is recovered. Let p(λ^{(l)}|bₗ=b, s) denote PDF of λ^{(l)} which can be obtained according to methods in [2]. An error happens when bₗ=0 (bₗ=1) is sent but λ^{(l)}<0 (λ^{(l)}≥0). Therefore, the bit error rate can be computed as follows:

$${P}_{e}^{( l )} = 0.5 \times {\int }_{- ∞}^{0} p ( {λ}^{( l )} \vert {b}_{l} = 0 , s ) d {λ}^{( l )} + 0.5 \times {\int }_{0}^{+ ∞} p ( {λ}^{( l )} \vert {b}_{l} = 1 , s ) d {λ}^{( l )} .$$

Let λᵢ denote the LLR for VN vᵢ which can be obtained from channel observations. The indices of the VNs which are assigned to the identified bit levels and have the amplitudes of their LLRs larger than a threshold ω may be selected to form the set [symbol] ₀ (step 1002), i.e., [symbol] ₀={i:(i mod m)∈ [symbol] and |λᵢ|>ω}. The value of the threshold ω can be large and fixed, e.g., 100. The value of the threshold ω can be the average of amplitudes of LLRs on the identified bit levels.

Although FIG. 10 illustrates one example of a process 1000 for identifying a set of indices of variable nodes, various changes may be made to FIG. 10. For example, while shown as a series of steps, various steps in FIG. 10 could overlap, occur in parallel, occur in a different order, or occur any number of times (including zero times).

A high level summary of a scheduling procedure consistent with the process 900 of FIG. 9 in conjunction with the process 1000 of FIG. 10 follows:
Identify [symbol] _{P}, the set of indices of VNs corresponding to punctured bits.
   The punctured bits are not transmitted.
   The initial LLRs {λᵢ:i∈ [symbol] _{P}} are set to zeros.
Identify [symbol] ₀, the set of indices of VNs corresponding to shortening bits.
   The shortening bits are always fixed to zeros, not transmitted and revealed to the decoder.
   The initial LLRs {λᵢ:i∈ [symbol] ₀} are set to +∞.
Identify [symbol] ₁, the set of indices of VNs corresponding to bits whose initial LLRs larger than a threshold (in terms of magnitudes).
Divide the row indices into subsets and sort the subsets both based on row weight at the punctured VNs [symbol] _{P}.
Sort the row indices within each subset based on the row weight excluding the elements at the VNs [symbol] ₀∪ [symbol] ₁.

For the example parity check matrix of FIG. 8 with rows {0, 1, 2, 3, 4} and columns {0, 1, 2, 3, 4, 5, 6, 7, 8, 9, 10, 11, 12, 13, 14}, the row indices are dived into subsets that are sorted in ascending order of two weight at positions 0 and 1—that is, {{4}, {1,3}, {0,2}}. Within each subset, the row indices are sorted in ascending order of row weight excluding the element s at positions {{5, 6, 7}, {12,13}} (the high LLRs and the shortening VNs, respectively). The resulting schedule is {{4}, {3,1}, {2,0}}.

FIG. 11 is a flowchart of an alternative example procedure 1100 for layered decoding according to embodiments of the present disclosure. For example, the procedure 1100 for layered decoding can be performed by the UE 116, the gNB 102, and/or network 130 in the wireless network 100 of FIG. 1, as part of the procedure 700 depicted in FIG. 7. This example is for illustration only and other embodiments can be used without departing from the scope of the present disclosure.

VNs having corresponding LLRs, calculated based on channel observations, with amplitudes larger than a threshold are identified and their indices form a set [symbol] ₁ (step 1101). One embodiment of identifying a set of VN indices is according to the procedure 1000 of FIG. 10.

A schedule A is generated by sorting indices of rows in an ascending order based on the row weight, excluding the elements at the identified indices and the indices of the shortening VNs (step 1002). Denote

$${ϕ}^{′} = \{ {ϕ}_{0}^{′} , {ϕ}_{1}^{′} , … , {ϕ}_{N - K - 1}^{′} \} .$$

The schedule A is a permuted version of [0:N−K−1]. Therefore, given ϕ′ᵢ and ϕ′ⱼ which are respectively i-th and j-th element in ϕ′ with i<j,

$$w ( {h}_{{ϕ}_{i}^{′} , [ 0 : N - 1 ] \backslash \{ {𝒮}_{0} , {𝒮}_{1} \}} ) \leq w ( {h}_{{ϕ}_{j}^{′} , [ 0 : N - 1 ] \backslash \{ {𝒮}_{0} ⋃ {𝒮}_{1} \}} ) .$$

In the case of

$$w ( {h}_{{ϕ}_{i}^{′} , [ 0 : N - 1 ] \backslash \{ {𝒮}_{0} , {𝒮}_{1} \}} ) = w ( {h}_{{ϕ}_{j}^{′} , [ 0 : N - 1 ] \backslash \{ {𝒮}_{0} ⋃ {𝒮}_{1} \}} ) ,$$

the order of ϕ′ᵢ and ϕ′ⱼ in the schedule can be arbitrary. In the example of FIG. 8, since the shortening VN indices are [symbol] ₀={12,13} and the high-LLR VN indices are [symbol] ₁={5,6,7}, the ordering of the row indices [0:4] is based on the corresponding row elements at indices [0:13]\{{12,13}∪{5,6,7}}= {0,1,2,3,4,8,9,10,11}. Since w(h_{4,{0,1,2,3,4,8,9,10,11}})=1<w(h_{3,{0,1,2,3,4,8,9,10,11}})=5<w(h_{1,{0,1,2,3,4,8,9,10,11}})=w(h_{2,{0,1,2,3,4,8,9,10,11}})=6<w(h_{0,{0,1,2,3,4,8,9,10,11}})=7, the resulting schedule A can be ϕ′={4,3,2,1,0} or ϕ′={4,3,1,2,0}.

Indices of rows of PCM are divided into subsets, each of which contains the indices of rows with the same number of non-zero elements at the indices of the punctured VNs (step 1103). Let ϕ^{(p)} [symbol] {j:w(h_{j,p})=p} denote the subset of the indices whose corresponding rows have p∈{0,1, . . . , P} non-zeros at the indices belonging to [symbol] . Then, the subsets {ϕ^{(p)}:p=0,1, . . . , P} are sorted in an ascending order of the number of non-zero elements of rows at the indices of the punctured VNs, which results in the set of indices shown as ϕ={ϕ⁽⁰⁾, ϕ⁽¹⁾, . . . , ϕ^{(P)}}.

A schedule B is generated by ordering the row indices within each subset in an ascending order based on the row weight, without considering the elements at the indices of the shortening VNs and the identified indices (step 1104). Denote \tilde{ϕ}={\tilde{ϕ}⁽⁰⁾, \tilde{ϕ}⁽¹⁾, . . . , \tilde{ϕ}^{(P)}} the schedule B which is a permuted version of ϕ. Therefore, given

$${\tilde{ϕ}}_{i}^{( p )} and {\tilde{ϕ}}_{j}^{( p )}$$

which are respectively i-th and j-th element in \tilde{ϕ}^{(p)} with i<j

$$w ( {h}_{{\tilde{ϕ}}_{i}^{( p )} , [ 0 : N - 1 ] \backslash \{ {𝒮}_{0} , {𝒮}_{1} \}} ) \leq w ( {h}_{{\tilde{ϕ}}_{j}^{( p )} , [ 0 : N - 1 ] \backslash \{ {𝒮}_{0} ⋃ {𝒮}_{1} \}} ) ,$$

where [0:N−1]\{ [symbol] ₀∪ [symbol] ₁} denotes the set of indices [0:N−1]={0,1, . . . , N−1} excluding the indices belonging to [symbol] ₀ or [symbol] ₁. For the sake of simplicity, \tilde{ϕ}={\tilde{ϕ}₍₀₎, \tilde{ϕ}₍₁₎, . . . , \tilde{ϕ}_{N-K-1}}.

The order of generating the schedule A and the schedule B can be arbitrary, which means the order of step 1102 and steps 1103-1104 can be arbitrary.

In the initial few iterations of the layered decoding, the CNs are processed in sequence according to the schedule B, i.e., \tilde{ϕ} (step 1105). When processing CN \tilde{ϕ}ⱼ, the messages are updated according to Equations (1), (2) and (3). In the remaining iterations of the layered decoding, the CNs are processed in sequence according to the schedule A, i.e., ϕ′ (also step 1105). When processing CN ϕ′ⱼ, the messages are updated according to Equations (1), (2) and (3).

Although FIG. 11 illustrates one example of a process 1100 for a layered decoding, various changes may be made to FIG. 11. For example, while shown as a series of steps, various steps in FIG. 11 could overlap, occur in parallel, occur in a different order, or occur any number of times (including zero times).

A scheduling procedure may sort the row indices based on row weight at the punctured VNs (in higher priority), as well as the number of shared VNs between rows. The number of VNs shared by CN i₁ and CN i₂ is equal to the weight of (hⱼ_{₁}_{,[0:N-1]} AND hⱼ_{₂}_{,[0:N-1]}). For the example parity check matrix of FIG. 8, an empty set { } is created. The set is updated by adding the row index 4 because the corresponding row has the smallest weight at positions 0 and 1, that is, the set becomes {4}. The set is then updated by adding the row indices {3,1}, because rows {3,1} have the smallest weight (of remaining rows, excluding {4}) at positions 0 and 1, and the weight of (h_{3,[0:N-1]} AND h_{4,[0:N-1]}) is larger than the weight of (h_{1,[0:N-1]} AND h_{4,[0:N-1]}). The set becomes {{4}, {3,1}}. The set is then updated by adding the row indices {2,0}, because rows {2,0} have the smallest weight of remaining rows at positions 0 and 1, and the weight of (h_{0,[0:N-1]} AND h_{1,[0:N-1]}) is larger than the weight of (h_{2,[0:N-1]} AND h_{1,[0:N-1]}). The resulting schedule is {{4}, {3,1}, {2,0}}.

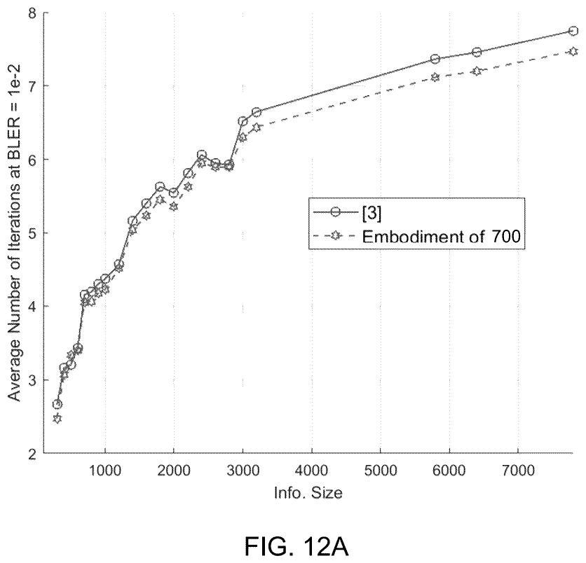

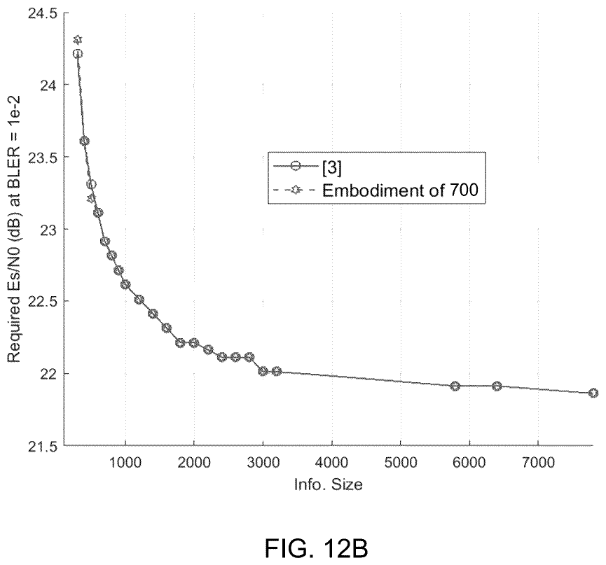

FIGS. 12A and 12B illustrate comparisons between LDPC decoding without and with above-described scheduling improvements in accordance with the present disclosure, in terms of average number of iterations and required ratio of average energy transmitted per channel symbol to average noise power (Es/N0). In all simulations, 5G NR LDPC codes, QAM256, and additive white Gaussian noise (AWGN) are applied. In addition, the code rate is 0.8 and the maximum number of iterations is 10. The target error rate is P=10⁻³. FIG. 12A shows a reduction in the average number of iterations between an embodiment of LDPC decoding according to the present disclosure (lower trace) and LDPC decoding according to [3] (upper trace). FIG. 12B shows that there is no significant increase in Es/N0.

Any of the above variation embodiments can be utilized independently or in combination with at least one other variation embodiment. The above flowchart illustrates example methods that can be implemented in accordance with the principles of the present disclosure and various changes could be made to the methods illustrated in the flowchart herein. For example, while shown as a series of steps, various steps in each figure could overlap, occur in parallel, occur in a different order, or occur multiple times. In another example, steps may be omitted or replaced by other steps.

Although the present disclosure has been described with exemplary embodiments, various changes and modifications may be suggested to one skilled in the art. It is intended that the present disclosure encompass such changes and modifications as fall within the scope of the appended claims. None of the descriptions in this application should be read as implying that any particular element, step, or function is an essential element that must be included in the claims scope. The scope of patented subject matter is defined by the claims.

What is claimed is:

1. A method for decoding low-density parity check (LDPC) codes in a communication system, the method comprising:
identifying a set of indices of variable nodes (VNs) having log-likelihood ratios (LLRs) greater than a threshold;
dividing indices of parity check matrix (PCM) rows into subsets each including a same number of non-zero row elements at indices of punctured VNs;
ordering the subsets of the indices of the PCM rows based on the number of non-zero row elements at the indices of the punctured VNs;
generating a schedule based on the ordered subsets of the indices of the PCM rows; and
performing layered LDPC decoding according to the schedule.

2. The method of claim 1, wherein the subsets of the indices of the PCM rows are ordered in ascending number of the non-zero row elements at the indices of the punctured VNs.

3. The method of claim 1, further comprising:
for each of the subsets of the indices of the PCM rows, ordering indices of the PCM rows within the respective subset based on row weight, excluding row elements at the identified set of indices of the VNs.

4. The method of claim 3, wherein the row weight for each of the PCM rows accounts for shortening VNs and high LLR VNs.

5. The method of claim 1, where performing layered LDPC decoding according to the schedule further comprises:
processing check nodes (CNs) in an order according to the schedule in each decoding iteration.

6. The method of claim 1, wherein generating a schedule based on the ordered subsets of the indices of the PCM rows comprises generating a first schedule and a second schedule, and
wherein ordering the subsets of the indices of the PCM rows based on the number of non-zero row elements at the indices of the punctured VNs forms the first schedule, the method further comprising:
ordering indices of the PCM rows on row weight, excluding row elements at the identified set of indices of the VNs, to form the second schedule,
wherein performing layered LDPC decoding according to the schedule comprises:
processing check nodes (CNs) in an order according to the second schedule in initial decoding iterations, and then in an order according to the first schedule in remaining decoding iterations.

7. The method of claim 1, wherein performing layered LDPC decoding according to the schedule further comprises:
performing decoding iterations according to a desired block error rate (BLER) is achieved.

8. An apparatus for decoding low-density parity check (LDPC) codes in a communication system, the apparatus comprising:
a transceiver configured to receive a signal having an associated LDPC code; and
at least one processor coupled to the transceiver and configured to decode the LDPC code by:
identifying a set of indices of variable nodes (VNs) having log-likelihood ratios (LLRs) greater than a threshold,
dividing indices of parity check matrix (PCM) rows into subsets each including a same number of non-zero row elements at indices of punctured VNs,
ordering the subsets of the indices of the PCM rows based on the number of non-zero row elements at the indices of the punctured VNs,
generating a schedule based on the ordered subsets of the indices of the PCM rows, and
performing layered LDPC decoding according to the schedule.

9. The apparatus of claim 8, wherein the subsets of the indices of the PCM rows are ordered in ascending number of the non-zero row elements at the indices of the punctured VNs.

10. The apparatus of claim 8, wherein the processor is configured to:
for each of the subsets of the indices of the PCM rows, ordering indices of the PCM rows within the respective subset based on row weight, excluding row elements at the identified set of indices of the VNs.

11. The apparatus of claim 10, wherein the row weight for each of the PCM rows accounts for shortening VNs and high LLR VNs.

12. The apparatus of claim 8, wherein the processor is configured to performing layered LDPC decoding according to the schedule by:
processing check nodes (CNs) in an order according to the schedule in each decoding iteration.

13. The apparatus of claim 8, wherein generating a schedule based on the ordered subsets of the indices of the PCM rows comprises generating a first schedule and a second schedule,
wherein ordering the subsets of the indices of the PCM rows based on the number of non-zero row elements at the indices of the punctured VNs forms the first schedule, and
wherein the processor is configured to
order indices of the PCM rows on row weight, excluding row elements at the identified set of indices of the VNs, to form the second schedule, and
process check nodes (CNs) in an order according to the second schedule in initial decoding iterations, and then in an order according to the first schedule in remaining decoding iterations.

14. The apparatus of claim 8, wherein the processor is configured to perform decoding iterations according to a desired block error rate (BLER) is achieved.

15. A non-transitory machine readable medium comprising instructions that, when executed by at least one processor of an electronic device, cause the electronic device to:
identify a set of indices of variable nodes (VNs) having log-likelihood ratios (LLRs) greater than a threshold,
divide indices of parity check matrix (PCM) rows into subsets each including a same number of non-zero row elements at indices of punctured VNs,
order the subsets of the indices of the PCM rows based on the number of non-zero row elements at the indices of the punctured VNs,
generate a schedule based on the ordered subsets of the indices of the PCM rows, and
perform layered LDPC decoding according to the schedule.

16. The non-transitory machine readable medium of claim 15, wherein the subsets of the indices of the PCM rows are ordered in ascending number of the non-zero row elements at the indices of the punctured VNs.

17. The non-transitory machine readable medium of claim 15, wherein the instructions that, when executed by the at least one processor of the electronic device, cause the electronic device to:
for each of the subsets of the indices of the PCM rows, order indices of the PCM rows within the respective subset based on row weight, excluding row elements at the identified set of indices of the VNs.

18. The non-transitory machine readable medium of claim 17, wherein the row weight for each of the PCM rows accounts for shortening VNs and high LLR VNs.

19. The non-transitory machine readable medium of claim 15, wherein the instructions that, when executed by the at least one processor of the electronic device, cause the electronic device to:
process check nodes (CNs) in an order according to the schedule in each decoding iteration.

20. The non-transitory machine readable medium of claim 15, wherein generating a schedule based on the ordered subsets of the indices of the PCM rows comprises generating a first schedule and a second schedule,
wherein ordering the subsets of the indices of the PCM rows based on the number of non-zero row elements at the indices of the punctured VNs forms the first schedule, and
wherein the instructions that, when executed by the at least one processor of the electronic device, cause the electronic device to
order indices of the PCM rows on row weight, excluding row elements at the identified set of indices of the VNs, to form the second schedule, and
perform layered LDPC decoding according to the schedule comprises:
processing check nodes (CNs) in an order according to the second schedule in initial decoding iterations, and then in an order according to the first schedule in remaining decoding iterations.
